(19) United States
(12) Patent Application Publication
(10) Pub. No.: US 2008/0105986 A1
(43) Pub. Date: May 8, 2008

(54) Electronic Device, a Chip Contacting Method and a Contacting Device

(75) Inventors: Hermann Schmid, Schwaig (DE); Enn Leong Tan, Kuala Lumpur (MY)

Correspondence Address: TEXAS INSTRUMENTS INCORPORATED, P O BOX 655474, M/S 3999, DALLAS, TX, 75265, US

(73) Assignee: TEXAS INSTRUMENTS, DEUTSCHLAND GMBH, Freising (DE)

(21) Appl. No.: 11/766,982

(22) Filed: Jun. 22, 2007

Related U.S. Application Data
(63) Continuation of application No. PCT/EP2005/014018, filed on Dec. 23, 2005.

(30) Foreign Application Priority Data
Dec. 23, 2004 (DE) 10 2004 062212.4

(51) Int. Cl. H01L 23/52

(52) U.S. Cl. 257/778; 257/E23.141

(57) ABSTRACT

An electronic device includes a chip (10) and a carrier substrate (16), wherein the carrier substrate (16) has a conductive structure (18) and the chip (10) has a pair of bonding pads (13) on a side facing the carrier substrate (16). The bonding pads (13) are in electrical contact with the conductive structure (18). The chip (10) has a non-reductive space layer (14) on the side facing the carrier substrate (16), wherein the non-conductive space layer (14) defines the distance between the chip (10) and the conductive structure (16) of the carrier substrate (16).

### FIELD OF THE INVENTION

The present invention relates generally to an electronic device which comprises a chip and a carrier substrate. The carrier substrate comprises a conductive structure and the chip comprises a pair of bonding pads on a side facing the carrier substrate. The bonding pads are in electrical contact with the conductive structure.

The present invention also relates to a chip contacting method for contacting multiple chips with multiple conductive structures. The multiple conductive structures are arranged on a common carrier substrate.

The present invention further relates to a contacting device for contacting multiple chips with multiple conductive structures, wherein the multiple conductive structures are arranged on a common carrier substrate.

### BACKGROUND OF THE INVENTION

When an electrical contact is established between the conductive structure of the carrier substrate and a bonding pad of the chip, process control and repeatability are very important for a stable and reliable device performance. A critical parameter when making an electrical contact between the conductive structure and the chip is the distance between the chip and the conductive structure. The distance determines the electrical impedance value of the electronic device. Examples of known contacting methods are the TAB (Tape Automated Bonding) method and the flip-chip contacting method. The TAB method is an automatic, simultaneous contacting technique in the case of which the chip is connected, by contact bumps deposited on the bonding pads, to the conductive structure of the carrier substrate which is typically a flexible strip of tape. For fastening the chips to the carrier substrate the contact bumps and the conductive structure are interconnected by a thermal node having a defined temperature-pressuretime profile. Also in the case of the flip-chip contacting method the electrical connection is established by contact bumps. According to this method the chip is fastened to the carrier substrate with the active side thereof thus connecting each bump to a corresponding inner lead of the carrier substrate.

Compressive force, temperature and a uniform distribution of the applied compressive force all over the device are critical parameters which must be precisely controlled for ensuring a well-defined distance between the chip and the conductive structure. The assembly process window thus is very small. Too high compressive forces can cause a deformation of the conductive structure of the carrier substrate so that the distance between the conductive structure and the chip becomes too small or is even reduced to zero. A direct contact between the chip and the conductive structure must absolutely be avoided. A further parameter which makes the process difficult to control is the material of the conductive structure which can be, for example, aluminum, copper, silver ink etc. Depending on the material the applied compressive force has to be varied to get a specific predetermined distance.

Another important process parameter is the speed of the contacting process. In the present time, the demands concerning the price of the electronic devices are continually increasing in view of the international competition. Thus, there is a strong need to produce the largest quantities of electronic components in a very short time for increasing the throughput which leads to a reduction of the costs involved with a specific process step.

The demands of highest repeatability and reliability are at present, with the conventional bonding methods and tools, incompatible with the demand of highest speed. Highest process speeds lead to a drastic decrease of the overall equipment accuracy and process repeatability.

### SUMMARY OF THE INVENTION

An aspect of the present invention provides an electronic device which is characterized by a very reliable and stable performance and which can be produced in a very cost-effective manner.

According to an aspect of the present invention the chip comprises a non-conductive space layer on the side facing the carrier substrate which defines the distance between the chip and the conductive layer of the carrier substrate. With this space layer the compression force applied during the bonding process becomes uncritical. Already very low compressive forces (1 to 2 N) are sufficient to fasten the chip to the carrier substrate. In the case of relatively high compression forces the space layer rests against the carrier substrate thus preventing a deformation of the conductive structure and providing a well-defined distance between the chip and the conductive structure of the carrier substrate all over the device. The thickness of the non-conductive space layer is essentially the same before the chip is electrically connected with the conductive structure of the carrier substrate and after the chip is electrically connected with the conductive structure of the carrier substrate so that a minimum distance between the chip and the conductive structure is predetermined by the thickness of this layer. Thus, the distance between the chip and the conductive structure is a parameter that can be reliably controlled when electrically connecting the chip with the conductive structure and it constitutes a well-defined parameter of the electronic device according to an aspect of the present invention.

According to an embodiment, the space layer is formed by a chip passivation layer. The passivation layer is grown much thicker than a conventional passivation layer growth step and with a well-defined thickness which precisely determines the distance between the chip and the conductive structure. A typical thickness of a thicker passivation layer according to an aspect of the present invention lies in the range of 15 to 20 um.

Alternatively, the space layer is formed by a mask layer for defining the contact bump. In this case, a special material is used ad the mask material and the mask is not removed after forming of the bump but is retained as a space layer for defining the distance between the chip and the conductive structure.

As a further alternative an aspect of the present invention provides that the space layer is a separately formed layer from a non-conductive material, e.g. from polyamide.

A further problem which arises with the rapid development of the layout and of the size of the electronic devices are the costs involved with these changes due to the need to adapt the design of the contacting tools to the new layouts and/or sizes. This problem arises to a high degree in the production of UHF/HF products which are requested in many different form factors and pitches. Current contacting tools are not designed to be flexible enough to meet these rapidly changing designs; they have to be redesigned in a very expensive manner.

An aspect of present invention also provides a chip contacting method for contacting multiple chips with multiple carrier substrates by means of which highest quantities of chips can be contacted in a very short time and with a very high process repeatability.

According to an aspect of the present invention, each of the multiple conductive structures is aligned with one of the multiple chips and each of the multiple chips is simultaneously contacted with one of the conductive structures on the common carrier substrate with the same contacting tool.

An aspect of present invention further provides a contacting device for contacting multiple chips with multiple carrier substrates by means of which high quantities of chips can be contacted in a very short time and with a very high process repeatability and which is characterized by a high flexibility to changes in layout and size of the chips and/or the conductive structures to be connected.

According to an aspect of the present invention, the contacting device comprises a force-transmitting element for simultaneously contacting each of the multiple chips with one of the conductive structures. The force-transmitting element has a main surface which corresponds in size at least to the size of the area the multiple conductive structures to be contacted simultaneously with the multiple chips take up on the common carrier substrate.

### BRIEF DESCRIPTION OF THE DRAWINGS

Further features and advantages of the invention read from the following description of embodiments in accordance with the present invention and with reference to the drawings in which:

FIG. 1 shows in a schematic manner a chip with a space layer and contact bumps according to a preferred embodiment of the present invention,

FIG. 2 shows in a schematic matter the chip of FIG. 1 facing a carrier substrate and a tool for fastening the chip to the carrier substrate,

FIG. 3 shows in a schematic manner a preferred embodiment of a chip contacting device according to the present invention.

### DETAILED DESCRIPTION

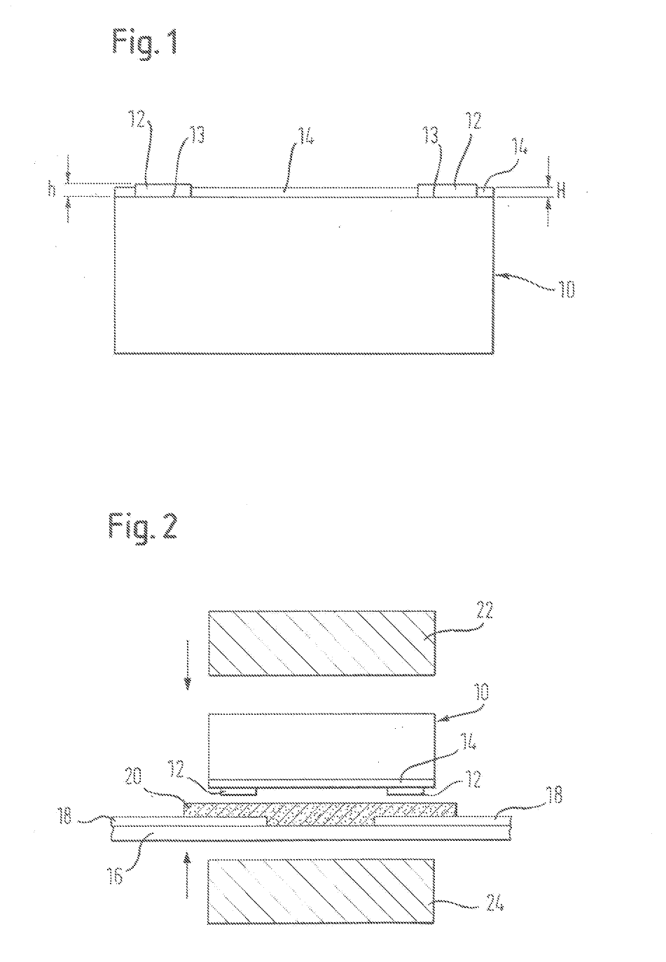

FIG. 1 shows a chip 10 with a pair of contact bumps 12 for establishing an electrical contact with a conductive structure of a carrier substrate which can be seen in FIG. 2. The contact bumps 12 are deposited on bonding pads 13 of the chip 10 and each have a height h. The surfaces of the contact bumps 12 facing away from the chip 10 are preferably substantially plane. On the same surface of the chip 10 on which the contact bumps 12 are deposited a non-conductive space layer 14 with a thickness H is provided. As can be seen in the FIG. 1, the thickness H of the non-conductive space layer 14 is slightly smaller than the height h of the contact bumps 12 so that the contact bumps 12 slightly protrude from the space layer 14. The difference in the thickness of space layer 14 and the height of the contact bumps 12, i.e. the distance which the contact bumps protrude from the non-conductive space layer 14, is between 3 pin and 12 pm. A typical material which the contact bumps 12 are made of is palladium (Pd). Other typical materials are nickel (Ni) and gold (Au).

In FIG. 2 the chip 10 of FIG. 1 faces a carrier substrate 16 which comprises a conductive structure 18. The conductive structure 18 preferably forms a strap with an antenna of a transponder. The transponder is preferably a UHF transponder. The carrier substrate 16 is preferably made of polyethylene (PET). An adhesive layer 20 is arranged on the surface of the carrier substrate 16 on which the conductive structure 18 is formed. The adhesive layer 20 partially covers the conductive structure 18. The adhesive layer 20 can be made from a non-conductive material or, alternatively, from a material which is conductive in a vertical direction, i.e. in a direction from the chip 10 to the conductive structure 18, and which is non-conductive in a horizontal direction, i.e. in a direction parallel to the upper surface of the carrier substrate 16. The adhesive layer 20 can be a thermosetting adhesive layer, for example, and is preferably configured as a printable adhesive paste. Above the chip 10 and beneath the carrier substrate 16 two healing blocks 22, 24 are arranged. The heating blocks 22 or 24 are mounted as to be vertically movable towards the chip 10 and towards the carrier substrate 16, respectively. In addition to heating the adhesive layer 20 the heating blocks 22, 24 also have the function to exert a predefined compressive force onto the chip 10 and t-le carrier substrate 16. The heating blocks 22, 24 are preferably parts of thermodes.

The non-conducting space layer 14 can be formed by the chip passivation layer. For that purpose, the passivation layer is grown much thicker than a conventional passivation layer growth step and with an exactly defined thickness since th3 thickness determines the distance between the chip 10 and the conductive structure 18. A typical thickness of a passivation layer according to the present invention lies in the range of 8 to 12 um.

Alternatively, the non-conductive space layer 14 is formed by the mask layer for defining the contact bumps 12. In this case, a special material is used as mask material and the mask material is not removed after the deposition of the contact bumps 12 but is retained as the space layer 14 for defining the distance between the chip 10 and the conductive structure 18.

As a further alternative the non-conductive space layer 14 is a separately formed layer made of a non-conductive material, e.g. from polyamide.

The conductive structure 18 can be manufactured from various materials, such as copper, aluminum, silver conducting paste, etc.

For fastening the chip 10 to the conductive structure 18, the carrier substrate 16 is brought into alignment with the chip 10 to be contacted. The upper heating block 22 is moved downwards towards the chip 10 and the lower heating block 24 is moved upwards towards the carrier substrate 16 to press the chip 10 with its contact humps 12 against the conductive structure 18 of the carrier substrate 16 with a predetermined compressive force. Subsequently, a predetermined temperature is applied to the system by the heating blocks 22, 24 to activate the adhesive layer 20. This activation of the adhesive layer 20 enables the contact bumps 12 of the chip 10 to abut on the conductive structure 18 of the carrier substrate 16. When the adhesive layer 20 has been activated, the predetermined compressive force is maintained until the chip 10 has been fixed due to curing of the adhesive layer 20, which means that the chip 10 is conductively connected to the carrier substrate 16. The non-conducting space layer 14 is not deformed during fastening of the chip 10 to the conductive structure 18. Also the contact bumps 12 are preferably not deformed during fastening of the chip 10.

With the electronic devices known from the prior art the compressive force applied curing the contacting process is very critical since it has a strong influence on the reliability and the performance of the device. A too low compressive force may result in an unreliable contact between the chip 10 and the conductive structure 18. A too high compressive force may result in a deformation of the conductive structure 18 so that the actual distance between the chip 10 and the conductive structure 18 varies from the predetermined distance. The deformation is caused by the contact bumps protruding from the chip surface. The distance the contact lumps protrude from the chip surface is typically about 20 um in the prior art devices. Since the adequate amount of compressive force also depends on the material the conductive structure 18 is made of, the distance is a parameter which is very difficult to control. However, since the distance between the chip 10 and the conductive structure 18 defines the electrical impedance value of the device and thus determines its performance, it is very important to ensure a well-defined distance between the chip 10 and the conductive structure 18 all over the device.

The chip 10 according to the present invention comprises the space layer 14 on the surface on which the contact bumps 12 to be contacted with the conductive structure 18 are arranged. Due to this additional space layer 14 from which the contact bumps 12 only protrude a very short distance compared with the chips known from the prior art, a deformation of the conductive structure 18 is prevented in the case of too high compressive forces since in that case the space layer 14 abuts on the carrier substrate 16 and prevents a deformation of the conductive structure 18. Thus, the surfaces of the pair of contact bumps 12 and the surface of the conductive structure 18 contacting each other are coplanar. With the space layer 14 abutting on the conductive structure 18 the electrical impedance value is determined by the thickness of this space layer 14. The distance the contact Lumps 12 protrude from the space layer 14 lies in range between 3 μm to 12 um.

Thus, when assembling an electronic device according to the present invention the amount and uniformity of the applied compressive forces become uncritical. The distance between the chip 10 and the conductive structure 18 is defined by the thickness of the space layer 14 which is easy to control and can therefore be provided in an exact manner. The electronic device according to the present invention is characterized by a high reliability and a very uniform product performance.

According to an aspect of the present invention, the electronic device shown in FIG. 2 of the drawings is a transponder, preferably a UHF (Ultra High Frequency) transponder. The conductive structure 18 on the carrier substrate 16 then forms a strap with an antenna of the transponder.

In chip contacting devices known from the prior art, each single conductive structure is connected with each single chip in a separate contacting step. For fastening the chip to the conductive structure each single chip is interconnected with each single conductive structure by a single thermal mode having a defined temperate re-pressuretime profile. This process step is repeated for each single electronic component to be assembled. The conductive structures arranged on the carrier substrate must have a minimum distance since otherwise the alignment of the thermal mode with respect to the chip to be contacted is too critical. This procedure does not comply with the demands of highest speed, highest quantities, highest reliability and highest uniformity in performance.

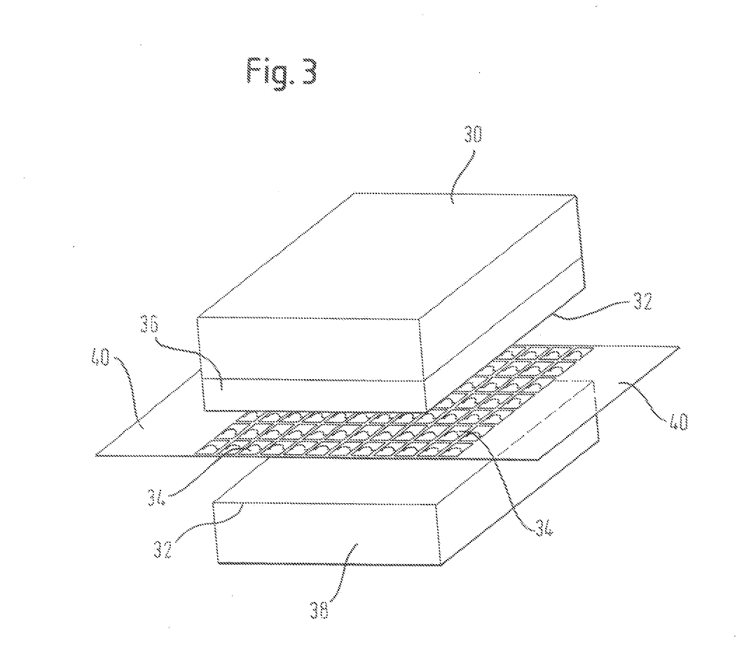

FIG. 3 of the drawings shows in a schematic manner a chip contacting device that meets the demands of highest speed, highest flexibility and highest process repeatability. The contacting device comprises a force-transmitting member 30 which has a main surface 32 which corresponds in size at least to the size of the area which the multiple conductive structures take up on the carrier substrate. As can be seen, in the preferred embodiment the multiple conductive structures 34 are arranged in an array. The array can be formed by 10×7 conductive structures 34, for example. The main surface 32 of the force-transmitting element 30 has the same size as the array of the conductive structures 34. In the preferred embodiment the force-transmitting element 30 comprises an elastic pi ate 36 which is preferably made from silicon rubber. In the embodiment shown in FIG. 3 in addition to an upper force-transmitting element 30 a lower force-transmitting element 38 is provided, wherein only the upper force-transmitting element 30 comprises the elastic plate 36. Between the upper and lower force-transmitting elements multiple conductive structures 34 are arranged on a common carrier substrate 40. Each of the multiple conductive structures 34 is brought into alignment with one of multiple chips (which are not seen in FIG. 3). With the help of the force-transmitting elements 30, 38 a predetermined compressive force can be simultaneously exerted onto the multiple chips and the multiple carrier substrates 34 for simultaneously contacting said multiple chips with the multiple conductive structures 34. The amount of the predetermined compressive force can be varied depending on the varying process parameters, specifically on the specific number of the chips and the conductive structure to be contacted simultaneously.

Since multiple chips and multiple conductive structures are interconnected simultaneously and with the same tool in the same process step a high uniformity of the applied compressive force from device to device is guaranteed. The speed of the process is drastically increased. Furthermore, the conductive structures can be arranged in very small pitches thus making use of the carrier substrate material in an efficient manner.

According to a preferred embodiment, the multiple conductive structures 34 and multiple chips are assembled for forming transponders, preferably UHF transponders. The conductive structures 34 then form straps with antennas of the transponders. The common carrier substrate 40 of the conductive structures is preferably an elastic tape.

While the invention has been particularly shown and described with reference to preferred embodiments thereof it is well understood by those skilled in the art that various changes and modifications can be made in the invention without departing from the spirit and scope of the invention as defined by the appended claims.

1. An electronic device comprising:
a chip (10)
a carrier substrate (16), said carrier substrate (16) comprising a conductive structure (18), said chip (10) comprising a pair of bonding pads (13) on a side facing said carrier substrate (16), said bonding pads (13) being in electrical contact with said conductive structure (18), and said chip (10) further comprising a non-conductive space layer (14) on said side facing said carrier substrate (16), said non-conductive space layer (14) defining the distance between said chip (10) and said conductive structure (16) of said carrier substrate (16).

2. The electronic device according to claim 1, wherein a contact bump (12) is formed on each of said bonding pads (13).

3. The electronic device according to claim 2, wherein said contact bump (12) protrudes from said non-conductive space layer (14) a distance between 3 um and 12 um.

4. The electronic device according to claim 1, wherein said non-conductive space layer (14) is formed by a chip passivation layer.

5. The electronic device according to claim 4, wherein said chip passivation layer has a thickness of 8 to 12 um.

6. The electronic device according to claim 1, wherein said nonconductive space layer (14) is made of polyamide.

7. The electronic device according to claim 1, wherein said nonconductive space layer (14) is formed by a mask layer for defining said contact bump (12).

8. The electronic device according to claim 1, wherein an adhesive layer (20) is provided on a surface of said carrier substrate (16) facing said chip (10).

9. The electronic device according to claim 1, wherein said carrier substrate (16) is a flexible tape.

10. The electronic device according to claim 1, wherein the electronic device is a transponder.

11. The electronic device according to claim 10, wherein said transponder is a UHF (Ultra High Frequency) transponder.

12. The electronic device according to claim 10, wherein said conductive structure (16) of said carrier substrate (16) forms an antenna.

13. The electronic device according to claim 2, wherein the surfaces of said pair of contact bumps (12) and of said conductive structure (18) facing each other are coplanar.

14. A chip contacting method for contacting multiple chips with multiple conductive structures (34), wherein said multiple conductive structures (34) are arranged on a common carrier substrate (40), comprising the steps of:
aligning each of said multiple conductive structures (34) with one of said multiple chips; and
simultaneously contacting each of said multiple chips with one of said conductive structures (34) on said common carrier substrate (40) with the same contacting tool.

15. The chip contacting method according to claim 14, wherein said multiple chips are simultaneously contacted with said conductive structures (34) by a force-transmitting element (30, 38) which has a main surface (32) which corresponds in size at least to the size of the area said multiple conductive structures (34) take up on said common carrier substrate (40).

16. The chip contacting method according to claim 14, wherein said multiple conductive structures (34) are arranged in an array on said common carrier substrate (40).

17. The chip contacting method according to claim 15, wherein said force-transmitting element (30) comprises an elastic plate (36).

18. The chip contacting method according to claim 17, wherein said elastic plate (36) is made of silicon rubber.

19. The chip contacting method according to claim 14, wherein said common carrier substrate (40) is a flexible tape.

20. A contacting device for contacting multiple chips with multiple conductive structures (34), wherein said multiple conductive structures (34) are arranged on a common carrier substrate (40), said contacting device comprising:
a force-transmitting element (30, 38) for simultaneously contacting each of said multiple chips with one of said conductive structures (34), said force-transmitting element (30, 38) having a main surface (32) corresponding in size at least to the size of the area said multiple conductive structures (34) to be contacted simultaneously with said multiple chips take up on said common carrier substrate (40).

21. The contacting device according to claim 20, wherein said force-transmitting element (30) comprises an elastic plate (36).

22. The contacting device according to claim 21, wherein said elastic plate (36) is made of silicon rubber.
